(19) United States
(12) Patent Application Publication
(10) Pub. No.: US 2017/0201408 A1
(43) Pub. Date: Jul. 13, 2017

(54) WIRELESS RECEIVER FOR CARRIER AGGREGATION

(71) Applicant: QUALCOMM Incorporated, San Diego, CA (US)

(72) Inventors: Yunfei FENG, San Diego, CA (US); Chuan WANG, San Diego, CA (US); Dongling PAN, San Diego, CA (US); Chiewcharn NARATHONG, Laguna Niguel, CA (US)

(21) Appl. No.: 15/176,105

(22) Filed: Jun. 7, 2016

Related U.S. Application Data
(60) Provisional application No. 62/277,885, filed on Jan. 12, 2016.

(51) Int. Cl. H04L 27/26; H03F 3/195; H03F 3/24; H04L 5/00; H03F 3/193

(52) U.S. Cl. CPC H04L 27/2691; H04L 5/0041; H03F 3/193; H03F 3/245; H03F 3/195; H03F 2200/171; H03F 2200/294; H03F 2200/451; H03F 2200/534; H03F 2200/255

(57) ABSTRACT

Wireless receivers are configured to support carrier aggregation. A device may include at least one low-noise amplifier (LNA). The device may also include a first input path configured to convey a first signal to a first input of the at least one LNA(s), and a second input path configured to convey a second signal to a second input of the LNA(s). Further, the device may include a transformer configured to inductively couple the first input path to the second input path.

### CROSS-REFERENCE TO RELATED APPLICATION

The present application claims the benefit of U.S. Provisional Patent Application No. 62/277,885, filed on Jan. 12, 2016, and titled “WIRELESS RECEIVER FOR CARRIER AGGREGATION,” the disclosure of which is expressly incorporated by reference herein in its entirety.

### BACKGROUND

Field

The present disclosure relates generally to electronic devices. More specifically, aspects of the present disclosure relate to wireless receivers configured to support carrier aggregation.

Background

A wireless device (e.g., a cellular phone or a smartphone) in a wireless communication system may transmit and receive data for two-way communication. The wireless device may include a transmitter for data transmission and a receiver for data reception. For data transmission, the transmitter may modulate a radio frequency (RF) carrier signal with data to obtain a modulated RF signal, amplify the modulated RF signal to obtain an amplified RF signal having the proper output power level, and transmit the amplified RF signal via an antenna to a base station. For data reception, the receiver may obtain a received RF signal via the antenna and may amplify and process the received RF signal to recover data sent by the base station.

A wireless device may support carrier aggregation, which is simultaneous operation on multiple carriers. A carrier may refer to a range of frequencies used for communication and may be associated with certain characteristics. For example, a carrier may be associated with system information describing operation on the carrier. A carrier may also be referred to as a component carrier (CC), a frequency channel, a cell, etc. It is desirable to efficiently support carrier aggregation by the wireless device.

### SUMMARY

In an aspect of the present disclosure, a device is presented. The device includes at least one low-noise amplifier (LNA). The device also includes a first input path configured to convey a first signal to a first input of the one or more LNAs. The device further includes a second input path configured to convey a second signal to a second input of the LNA(s). Additionally, the device includes a transformer configured to inductively couple the first input path to the second input path.

In another aspect of the present disclosure, a method is presented. The method includes receiving an input signal at a first input path. The method also includes amplifying the input signal with a first low-noise amplifier (LNA) to operate in one of an inter-carrier aggregation (CA) mode, a non-CA mode, or an intra-CA mode. The method further includes inductively coupling the first input path including the input signal with a second input path to generate a second input signal. Additionally, the method includes amplifying each of the input signal and the second input signal with each of the first LNA and a second LNA to operate in the intra-CA mode.

In yet another aspect of the present disclosure, a device is presented. The device includes means for receiving an input signal at a first input path. The device also includes means for amplifying the input signal to operate in one of an inter-carrier aggregation (CA) mode, a non-CA mode, or an intra-CA mode. The device further includes means for inductively coupling the first input path including the input signal with a second input path to generate a second input signal. Additionally, the device includes means for amplifying each of the input signal and the second input signal to operate in the intra-CA mode.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 shows a wireless device communicating with a wireless system, according to an aspect of the present disclosure.

FIG. 2 shows a block diagram of the wireless device in FIG. 1, according to an aspect of the present disclosure.

FIG. 3 illustrates a device including a low-noise amplifier, a mixer, and a baseband filter, according to an aspect of the present disclosure.

FIGS. 4A-4C depict various matching circuits, according to aspects of the present disclosure.

FIG. 5 illustrates a device including low-noise amplifiers, mixers, and baseband filters, according to an aspect of the present disclosure.

FIG. 6 depicts a device including multiple receive paths, according to an aspect of the present disclosure.

FIG. 7 illustrates the device of FIG. 6 during one contemplated operational mode, in accordance with an aspect of the present disclosure.

FIG. 8 illustrates the device of FIG. 6 during another contemplated operational mode, according to an aspect of the present disclosure.

FIG. 9 illustrates the device of FIG. 6 during another contemplated operational mode, according to an aspect of the present disclosure.

FIG. 10 illustrates the device of FIG. 6 during another contemplated operational mode, in accordance with an aspect of the present disclosure.

FIG. 11 illustrates the device of FIG. 6 during yet another contemplated operational mode, according to an aspect of the present disclosure.

FIG. 12 is a flowchart depicting a method, in accordance with an aspect of the present disclosure.

FIG. 13 illustrates a filter device, according to an aspect of the present disclosure.

### DETAILED DESCRIPTION

The detailed description set forth below in connection with the appended drawings is intended as a description of exemplary embodiments and is not intended to represent the only embodiments in which the present disclosure can be practiced. The term “exemplary” used throughout this description means “serving as an example, instance, or illustration,” and should not necessarily be construed as preferred or advantageous over other exemplary embodiments. The term “coupled” used throughout this description means “connected, whether directly or indirectly through intervening connections, electrical, mechanical, or otherwise,” and is not necessarily limited to physical connections. Additionally, the connection can be such that the objects are permanently connected or releasably connected. The detailed description includes specific details for the purpose of providing a thorough understanding of the exemplary embodiments. It will be apparent to those skilled in the art that the exemplary embodiments may be practiced without these specific details. In some instances, well-known structures and devices are shown in block diagram form in order to avoid obscuring the novelty of the exemplary embodiments presented herein.

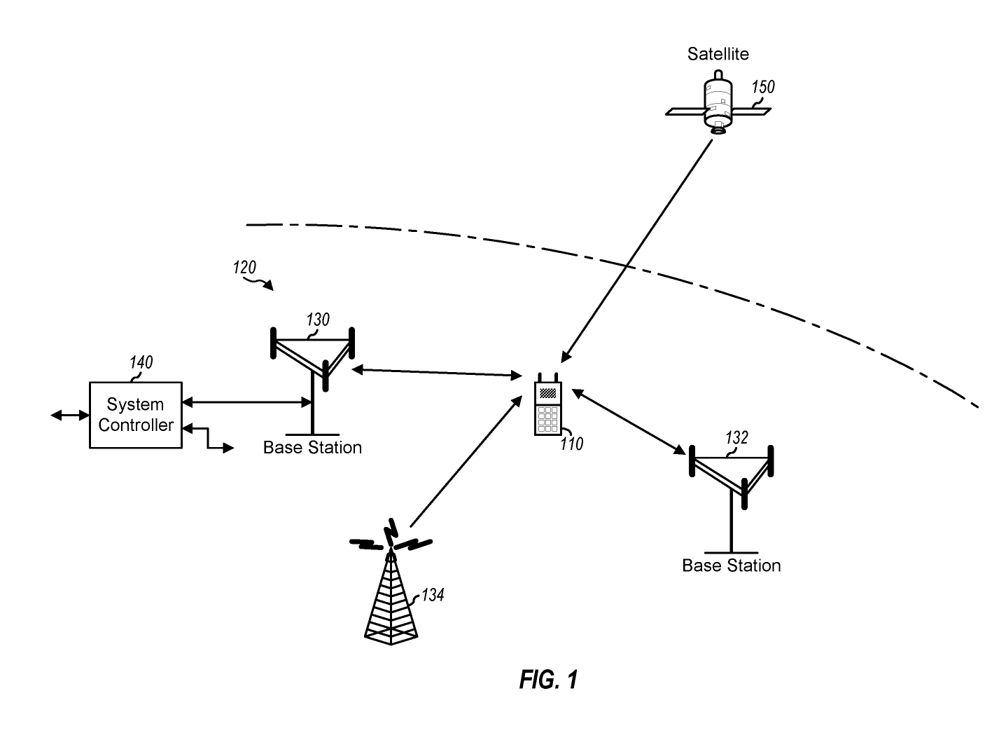

FIG. 1 shows a wireless device 110 communicating with a wireless communication system 120. Wireless system 120 may be a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), CDMA 1X, evolution-data optimized (EVDO), time division synchronous CDMA (TD-SCDMA), or some other version of CDMA. For simplicity, FIG. 1 shows wireless system 120 including two base stations 130 and 132 and one system controller 140. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1X, EVDO, TD-SCDMA, GSM, 802.11, etc.

Wireless device 110 may support carrier aggregation, which is operation on multiple carriers. Carrier aggregation may also be referred to as multi-carrier operation. Wireless device 110 may be able to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz and 3400 to 3800 MHz. Low-band, mid-band, and high-band refer to three groups of bands (or band groups), with each band group including a number of frequency bands (or simply, “bands”). Each band may cover up to 200 MHz and may include one or more carriers. Each carrier may cover up to 20 MHz in LTE. LTE Release 11 supports 35 bands, which are referred to as LTE/UMTS bands and are listed in 3GPP TS 36.101. Of course, the ranges for the bands are merely exemplary and not limiting, and other frequency ranges may be used. Wireless device 110 may be configured with up to five carriers in one or two bands in LTE Release 11.

In general, carrier aggregation (CA) may be categorized into two types: intra-band CA and inter-band CA. Intra-band CA refers to operation on multiple carriers within the same band and inter-band CA refers to operation on multiple carriers in different bands.

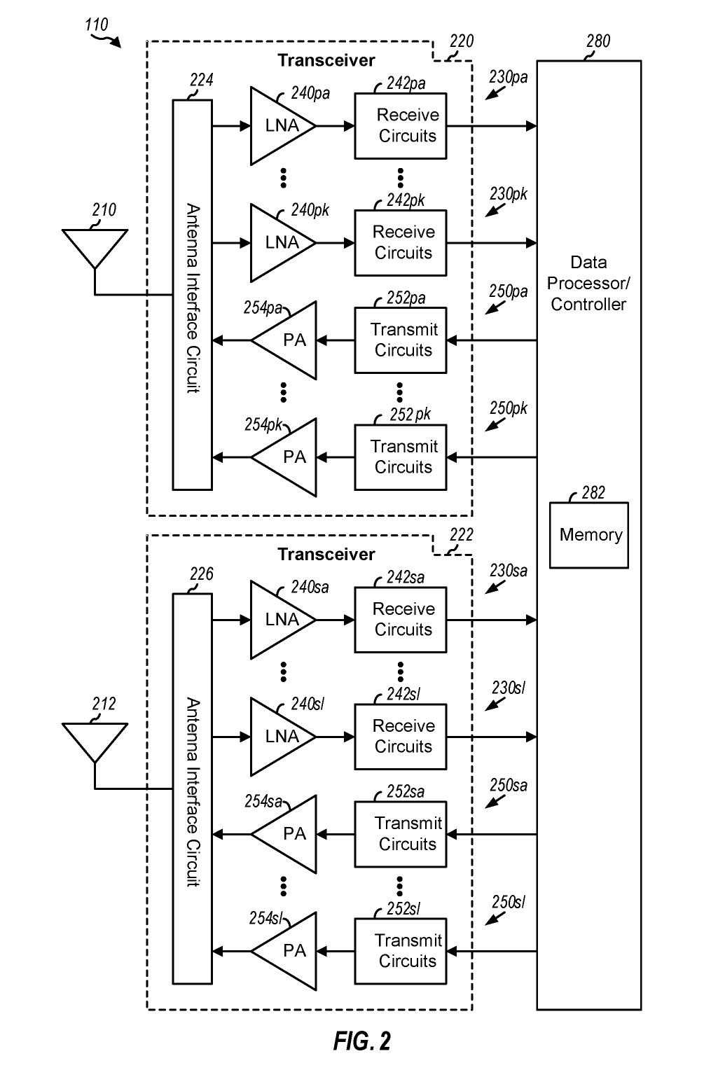

FIG. 2 shows a block diagram of an exemplary design of wireless device 110 in FIG. 1. In this exemplary design, wireless device 110 includes a transceiver 220 coupled to a primary antenna 210, a transceiver 222 coupled to a secondary antenna 212, and a data processor/controller 280. Transceiver 220 includes multiple (K) receivers 230pa to 230pk and multiple (K) transmitters 250pa to 250pk to support multiple frequency bands, multiple radio technologies, carrier aggregation, etc. Transceiver 222 includes L receivers 230sa to 230s1 and L transmitters 250sa to 250s1 to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230 includes an LNA 240 and receive circuits 242. For data reception, antenna 210 receives signals from base stations and/or other transmitter stations and provides a received radio frequency (RF) signal, which is routed through an antenna interface circuit 224 and presented as an input RF signal to a selected receiver 230. Antenna interface circuit 224 may include switches, duplexers, transmit filters, receive filters, matching circuits, etc. The description below assumes that receiver 230pa is the selected receiver. Within receiver 230pa, an LNA 240pa amplifies the input RF signal and provides an output RF signal. Receive circuits 242pa downconvert the output RF signal from RF to baseband, amplify and filter the downconverted signal, and provide an analog input signal to data processor 280. Receive circuits 242pa may include mixers, filters, amplifiers, matching circuits, an oscillator, a local oscillator (LO) generator, a phase locked loop (PLL), etc. Each remaining receiver 230 in transceivers 220 and 222 may operate in a similar manner as receiver 230pa.

In the exemplary design shown in FIG. 2, each transmitter 250 includes transmit circuits 252 and a power amplifier (PA) 254. For data transmission, data processor 280 processes (e.g., encodes and modulates) data to be transmitted and provides an analog output signal to a selected transmitter. The description below assumes that transmitter 250pa is the selected transmitter. Within transmitter 250pa, transmit circuits 252pa amplify, filter, and upconvert the analog output signal from baseband to RF and provide a modulated RF signal. Transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through antenna interface circuit 224 and transmitted via antenna 210. Each remaining transmitter 250 in transceivers 220 and 222 may operate in a similar manner as transmitter 250pa.

FIG. 2 shows an exemplary design of receiver 230 and transmitter 250. A receiver 230 and a transmitter 250 may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240 and receive circuits 242 within transceivers 220 and 222 may be implemented on multiple ICs, as described below. The circuits in transceivers 220 and 222 may also be implemented in other manners.

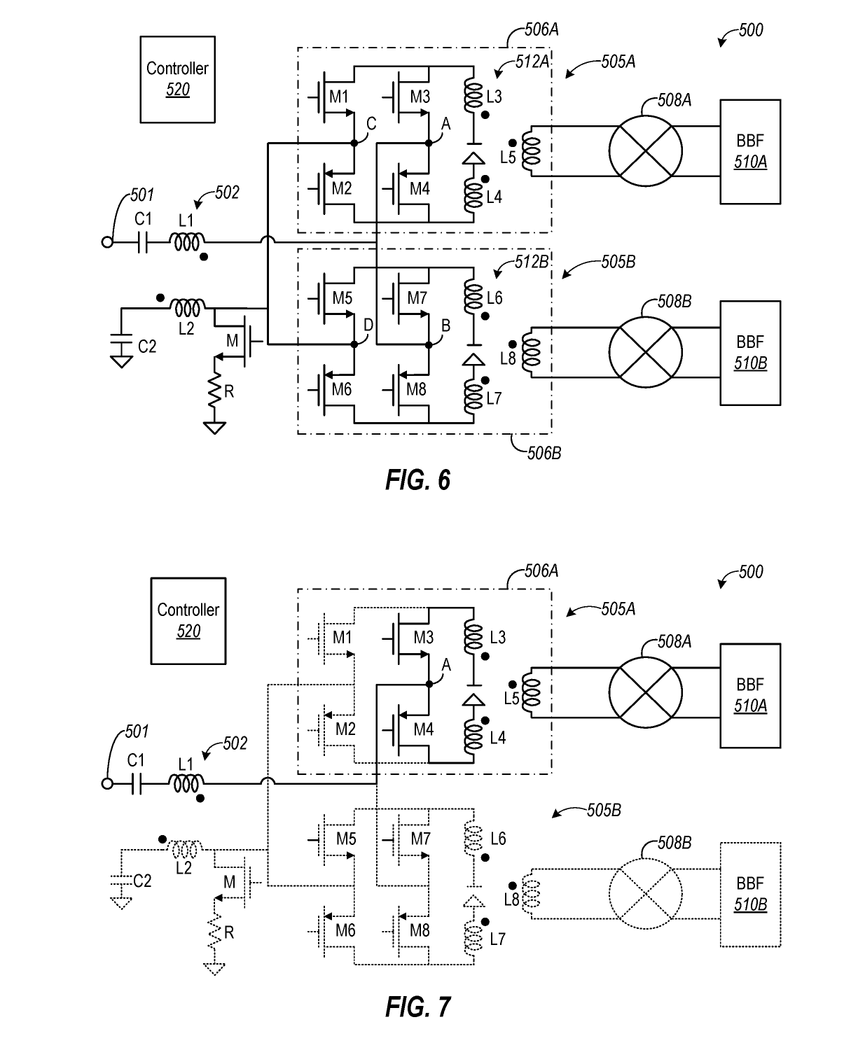

Data processor/controller 280 may perform various functions for wireless device 110. For example, data processor 280 may perform processing for data being received via receivers 230 and data being transmitted via transmitters 250. Controller 280 may control the operation of the various circuits within transceivers 220 and 222. In some aspects, transceivers 220 and 222 may also comprise a controller (by way of example only, see controller 520 of FIG. 6) to control various circuits within the respective transceiver (e.g., LNAs 240). A memory 282 may store program codes and data for data processor/controller 280. Data processor/controller 280 may be implemented on one or more application specific integrated circuits (ASICs) and/or other ICs.

Wireless device 110 may support CA and may (i) receive multiple downlink signals transmitted by one or more cells on multiple downlink carriers at different frequencies and/or (ii) transmit multiple uplink signals to one or more cells on multiple uplink carriers. Transmitters and receivers to support CA may be implemented on a single IC. However, it may be difficult or not possible to meet isolation requirements between the transmitters and receivers in certain transmit (TX) and receive (RX) bands due to limited pin-to-pin isolation on the IC.

For example, in the inter-CA mode, the isolation requirement between some TX and RX bands (e.g., UMTS Bands 4 and 17) may be 100 decibels (dB), which may be difficult or not possible to achieve because pin-to-pin isolation is worse than the isolation requirement. On-chip transmit filtering may improve pin-to-pin RX/TX isolation but (i) may degrade transmitter performance and (ii) may not reduce other RX/TX coupling mechanisms on the same IC. Furthermore, spurious signals from multiple PLLs and LO generators operating simultaneously on the same IC may degrade transmitter performance. Sensitivity of a receiver may also be degraded due to poor spurious and isolation performance.

In an aspect of the present disclosure, expandable transceivers and receivers implemented on multiple ICs may be used to support CA and mitigate the problems described above. Transmitters and receivers on the multiple ICs may be selected for use such that interference between these transmitters and receivers may be mitigated. As an example, for inter-band CA, a transmitter and a receiver on one IC may be used for communication on one band, and another transmitter and another receiver on another IC may be used for communication on another band. This may mitigate spurious and isolation problems encountered in the single-chip design. The teachings and claims herein also pertain to single-chip, as well as, single module and multiple module solutions. Multiple IC solutions are discussed as one example only.

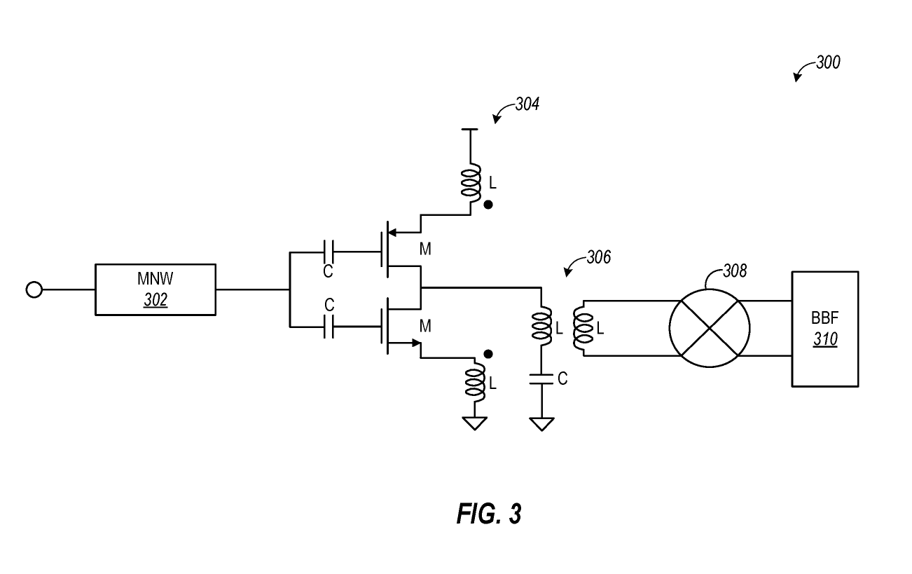

FIG. 3 depicts a device 300, which may comprise a receive path of a wireless receiver. Device 300, which may be coupled to a radio frequency (RF) front-end, includes a matching network (MNW) 302, a low-noise amplifier (LNA) 304, a transformer 306, a mixer 308 and a baseband filter 310.

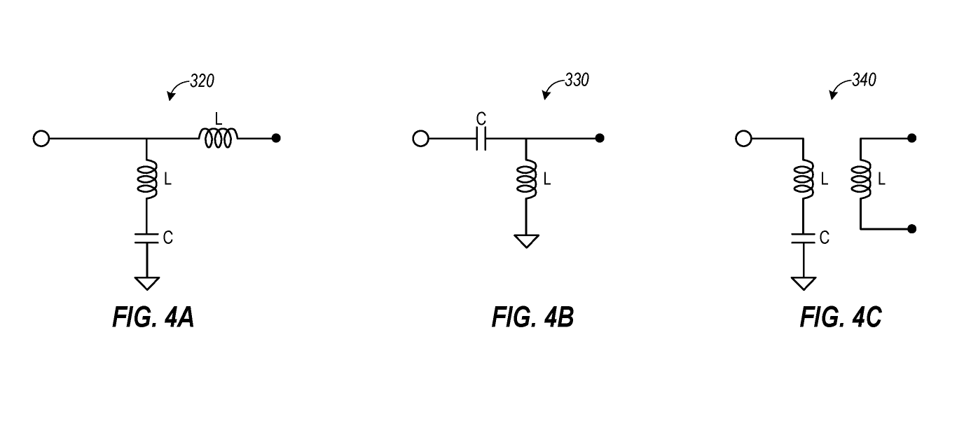

FIGS. 4A-4C depict various matching networks that may be used for matching network 302. Specifically, FIG. 4A depicts a matching network 320 including a plurality of inductors L and a capacitor C. FIG. 4B depicts a matching network 330 including a capacitor C and an inductor L. FIG. 4C depicts a matching network 340 including inductors L, which form a transformer, and a capacitor C.

As will be appreciated, device 300 (see FIG. 3) may have a high input impedance and may be matched for a 50 ohm interface via matching network 302 or with traditional narrow-band LC matching networks (e.g., matching networks 320, 330, and 340 of FIGS. 4A-4C), which work with only one fixed impedance.

Aspects of the present disclosure, as described herein, relate to wireless receivers configured to support carrier aggregation. According to one aspect, a device may include at least one low-noise amplifier (LNA). The device may also include a first input path configured to convey a first signal to a first input of the at least one LNA, and a second input path configured to convey a second signal to a second input of the at least one LNA. The device may also include a transformer configured to inductively couple the first input path to the second input path.

According to another aspect, the present disclosure includes methods for operating a wireless receiver. Various aspects of such a method may include receiving an input signal at a first input path. The method may further include amplifying the input signal with a first low-noise amplifier (LNA) to operate in one of an inter-carrier aggregation (CA) mode and a non-CA mode. Moreover, the method may include inductively coupling the first input path including the input signal with a second input path to generate a second input signal. In addition, the method may include amplifying each of the input signal and the second input signal with each of the first LNA and a second LNA to operate in an intra-CA mode.

Other aspects, as well as features and advantages of various aspects, will become apparent to those of skill in the art though consideration of the ensuing description, the accompanying drawings and the appended claims.

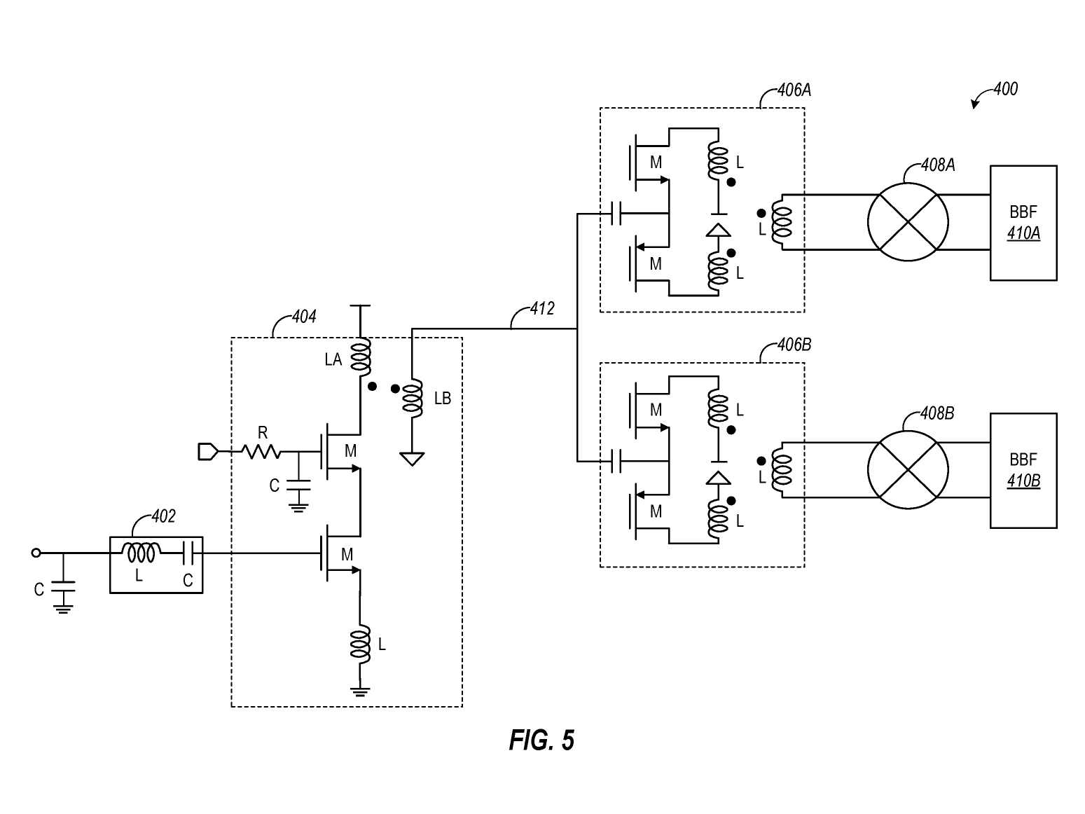

FIG. 5 depicts a device 400 including a matching network 402, LNA 404, receiver LNAs 406A and 406B, mixers 408A and 408B and baseband filters (BBFs) 410A and 410B. LNA 404, which may be external to a receiver module, includes a transformer including inductors LA and LB, and is coupled to receiver LNAs 406A and 406B via a transmission line 412.

In one aspect, linearity requirements of an LNA external to a receiver module (e.g., LNA 404) may become more stringent for an interface LNA (e.g., an LNA within the receiver module, such as LNAs 406A and 406B, for instance). Further, current-mode operation of an external LNA (e.g., LNA 404) with receiver LNAs (e.g., LNAs 406A and/or LNA 406B) may provide improved performance with respect to linearity (e.g., super linearity). However, in current-mode operation, an excessive gain loss of one or more interface LNAs (e.g., LNAs 406A and/or LNA 406B) in intra-CA mode, due to signal current splitting, may exist.

FIG. 6 illustrates a device 500, in accordance with an aspect of the present disclosure. As a non-limiting example, device 500 may be part of transceiver 220 and or transceiver 222 (see FIG. 2). More specifically, device 500 may be part of or distributed among antenna interface circuits 224/226, LNAs 240, receive circuits 242, or any combination thereof. Device 500 includes an input 501 and a transformer 502, which includes inductors L1 and L2. Device 500 further includes capacitors C1 and C2, a transistor M, and a resistor R.

Device 500 also includes a first receive path 505A including LNA 506A, mixer 508A, and baseband filter 510A. LNA 506A, which may comprise a current-mode LNA, includes transistors M1-M4, and a transformer 512A, which includes inductors L3-L5. Moreover, device 500 includes a second receive path 505B including LNA 506B, mixer 508B, and baseband filter 510B. LNA 506B, which may comprise a current-mode LNA, includes transistors M5-M8, and a transformer 512B, which includes inductors L6-L8.

As illustrated, inductor L1 of transformer 502 is coupled to each of a node A (e.g., between transistor M3 and M4) of LNA 506A and a node B (e.g., between transistor M7 and M8) of LNA 506B. In addition, inductor L2 of transformer 502 is coupled to each of a node C (e.g., between transistor M1 and M2) of LNA 506A and a node D (e.g., between transistor M5 and M6) of LNA 506B.

As depicted in FIG. 6, the sources of transistors M1 and M2 may be coupled together, the drains of transistors M1 and M3 may be coupled together, and the drains of transistors M2 and M4 may be coupled together. The drains of transistors M1 and M3 may be further coupled to inductor L3, and the drains of transistors M2 and M4 may be further coupled to inductor L4. Each of inductor L3 and inductor L4 is also coupled to a ground. Moreover, the sources of transistors M5 and M6 may be coupled together, the drains of transistors M5 and M7 may be coupled together, and the drains of transistors M6 and M8 may be coupled together. The drains of transistors M5 and M7 may be further coupled to inductor L6, and the drains of transistors M6 and M8 may be further coupled to inductor L7.

As will be understood by a person having ordinary skill in the art, the gates of each of transistors M and M1-M8 may be configured to receive a control signal from a controller 520, for example. Controller 520 may be coupled to each of the components of device 500 but is shown without connections for ease of illustration. In some aspects, controller 520 may be used to control the device 500 to operate in a CA mode or a non-CA mode. As described more fully below, device 500 may be configured for various modes of operation.

As will be further understood, each LNA 506 may receive a signal via one or two input paths. More specifically, each LNA 506 may receive a first input signal via a first input path including inductor L1 and a second input signal via a second input path including inductor L2.

In current-mode operation, LNAs 506 may exhibit a low input impedance, and a first stage LNA (not shown in FIG. 6; see FIG. 5) may provide sufficient gain. In one aspect, the first stage LNA may comprise an external LNA. Further, LNAs 506, including complementary common-gate (CG) with a 3-winding coupled transformer (e.g., transformer 512), may provide improved third order intercept point (IIP3) performance (e.g., >18 dBm). Of course, the performance is merely exemplary and the performance may vary according to design specifications and preferences. In addition, device 500 may be configured to support intra-CA mode operation as well, with similar or even better IIP3 performance compared to non-CA operation. Moreover, transformer 502 may provide additional signal current (e.g., to resolve gain loss issue due to signal splitting). More specifically, each LNA 506 includes two input paths. Therefore, each LNA may receive two input signals (e.g., one via inductor L1 and one via inductor L2), which may provide additional signal current.

FIG. 7 depicts device 500 in accordance with an aspect of the present disclosure. The device 500 may be operated in a CA mode, a non-CA mode, an interband CA mode using one first stage LNA (e.g., wideband LNA), or interband CA mode using multiple LNAs, for example, based on a control signal supplied via controller 520. As illustrated by way of example, in FIG. 7, device 500 may be operated in a current-mode inter-CA (or non-CA) mode. In this mode, input 501 is coupled to node A via capacitor C1 and inductor L1. As will be appreciated by a person having ordinary skill, in this mode, at least a portion of first receive path 505A is operating (e.g., turned ON) and second receive path 505B of device 500 is not operating (e.g., turned OFF) based on a control signal supplied via controller 520. In addition, in this aspect, inductors L1 and L2 are not inductively coupling and, thus, a signal is not generated at inductor L2. Further, transistors M1 and M2 of LNA 506A are in a non-conductive state and transistors M3 and M4 are in a conductive state. During a contemplated operation of the device 500 illustrated in FIG. 7, a signal received at input 501 is amplified by LNA 506A, downconverted to baseband by mixer 508A, and filtered by baseband filter 510A.

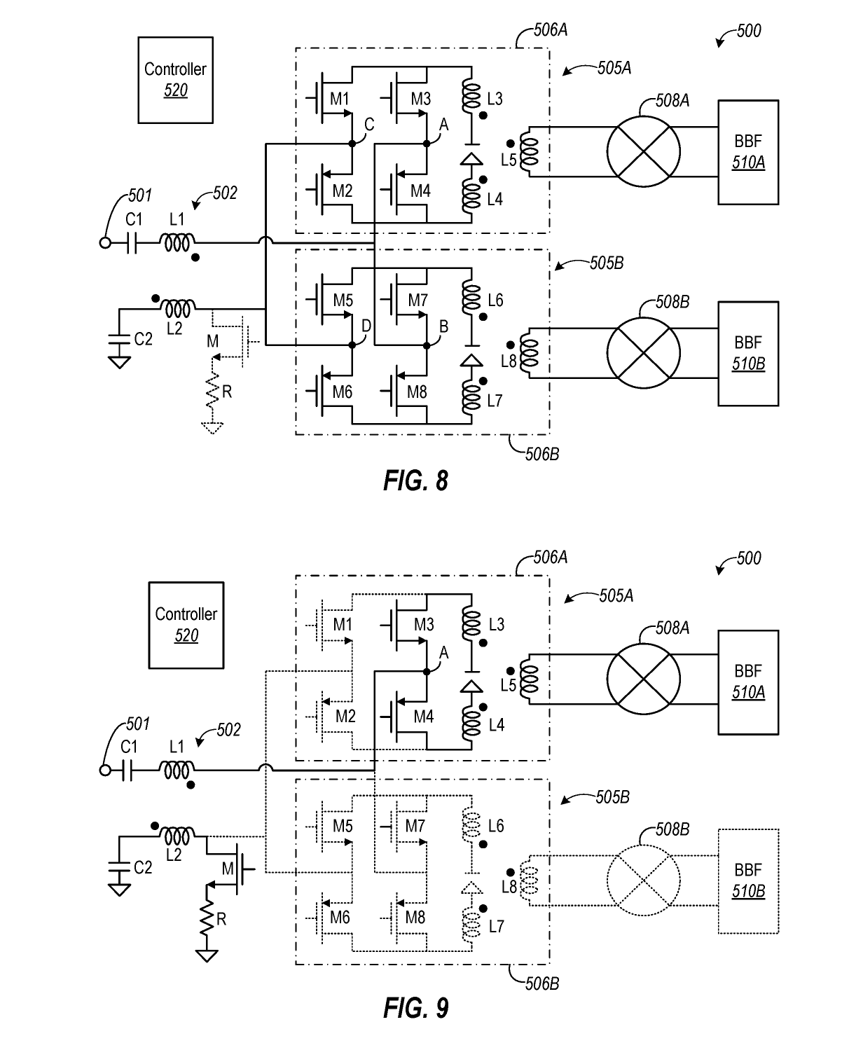

FIG. 8 illustrates device 500 in a current mode intra-CA operation. In this embodiment, an input transformer may be used to duplicate an input signal at inductor L1 to an additional signal at inductor L2 to resolve the excessive gain loss issue, as disclosed above (e.g., due to signal splitting). In this mode, input 501 is coupled to each of node A of LNA 506A and node B of LNA 506B (e.g., via capacitor C1 and inductor L1). Further, transformer 502 is operating and, thus, a signal, generated at inductor L2, is conveyed to each of node C of LNA 506A and node D of LNA 506B (e.g., via inductor L2). During a contemplated operation of the embodiment illustrated in FIG. 8, a signal received at input 501 and a signal generated at inductor L2 (e.g., via inductive coupling of inductor L1 and L2) are conveyed to LNA 506A, which provides amplification based on the signal received at node A and the signal received at node C. Further, mixer 508A downconverts an amplified signal (e.g., the signal output from LNA 506A) to baseband, and baseband filter 510A filters the baseband signal conveyed by mixer 508A. Furthermore, a signal received at input 501 and a signal generated at inductor L2 (e.g., via inductive coupling of inductor L1 and L2) are conveyed to LNA 506B, which provides amplification based on the signal received at node B and the signal received at node D. Further, mixer 508B downconverts an amplified signal (e.g., the signal output from LNA 506B) to baseband, and baseband filter 510B filters the baseband signal conveyed by mixer 508B.

FIG. 9 depicts an exemplary aspect of the present disclosure wherein device 500 is configured to operate in an inter-CA (or non-CA) mode. In some aspects, device 500 of FIG. 9, may also be operated in interband CA mode using one first stage LNA (e.g., wideband LNA), or interband CA mode using multiple LNAs. As shown in FIG. 9, based on a control signal supplied via controller 520, second receive path 505B of device 500 is not operating (e.g., turned OFF). However, controller 520 may provide a signal such that transformer 502 is operating, and transistor M is conducting, and thus, a signal generated at inductor L2 (e.g., via the inductive coupling between inductor L1 and L2) is conveyed to ground via resistor R. As will be appreciated, coupling inductor L2 to ground via transistor M and resistor R may modify the input impedance of LNA 506A (e.g., from substantially 20 ohms to substantially 50 ohms). In addition, transistors M1 and M2 of LNA 506A are in a non-conductive state and transistors M3 and M4 are in a conductive state based on a signal supplied via controller 520.

During a contemplated operation of the device 500 illustrated in FIG. 9, a signal received at input 501 is conveyed to node A of LNA 506A, which provides amplification. Further, mixer 508A downconverts an amplified signal (e.g., the signal output from LNA 506A) to baseband, and baseband filter 510A filters the baseband signal conveyed by mixer 508A. Further, as noted above, a signal generated at inductor L2 may be bled to ground via transistor M and resistor R.

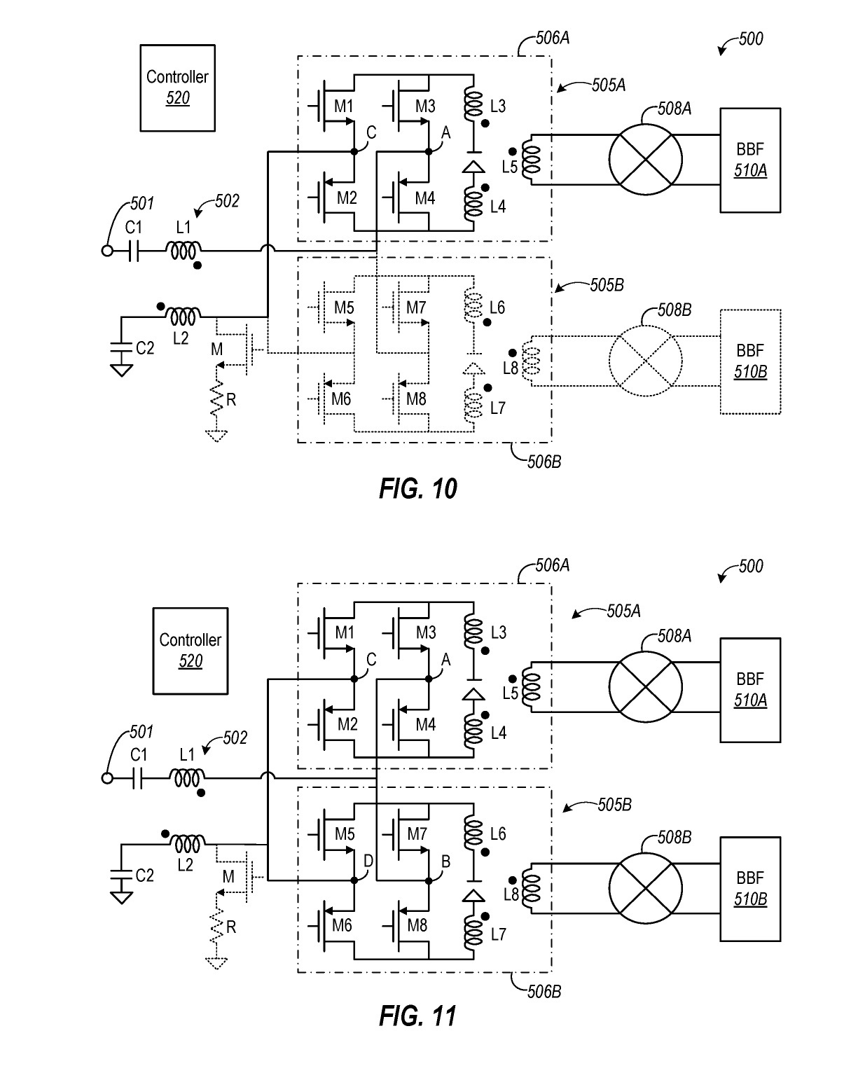

FIG. 10 depicts an aspect of the present disclosure, wherein device 500 is configured to operate in an inter-CA (or non-CA) mode. In this aspect, based on a control signal supplied via controller 520, transistors M1-M4 of LNA 506A are in a conductive state, and transistors M5-M8 are in a non-conductive state. Moreover, in this aspect, transformer 502 is operating and, thus, a signal is conveyed to each of node A via inductor L1 and node C via inductor L2. Further, in this aspect, transistor M may be controlled to be in a non-conductive state via a control signal from controller 520. It is noted that due to additional transistors (e.g., transistor M1 and M2) within LNA 506A being in a conductive state, an input impedance of LNA 506A may be modified (e.g., in comparison to when transistors M1 and M2 are in a non-conductive state). By way of example only, in the example of FIG. 10, the input impedance of LNA 506A may be modified from substantially 20 ohms to substantially 50 ohms.

During a contemplated operation in the exemplary aspect illustrated in FIG. 10, a signal received at input 501 and a signal generated at inductor L2 (e.g., via inductive coupling of inductor L1 and L2) are conveyed to LNA 506A, which provides amplification based on the signal received at node A and the signal received at node C. Further, mixer 508A downconverts an amplified signal (e.g., the signal output from LNA 506A) to baseband, and baseband filter 510A filters the baseband signal conveyed by mixer 508A.

FIG. 11 depicts yet another exemplary aspect wherein device 500 is operating in an intra-CA operation. In some aspects, device 500 of FIG. 11, may also be operated in interband CA mode using one first stage LNA (e.g., wideband LNA), or interband CA mode using multiple LNAs. In this aspect, both first receive path 505A and second receive path 505B are operating (e.g., turned ON). Moreover, in this aspect, transformer 502 is operating and transistor M is controlled to be in a non-conductive state (e.g., via controller 520).

During a contemplated operation of the device 500 illustrated in FIG. 11, a signal received at input 501 and a signal generated at inductor L2 (e.g., via inductive coupling of inductor L1 and L2) are conveyed to LNA 506A, which provides amplification based on the signal received at node A and the signal received at node C. Further, mixer 508A downconverts an amplified signal (e.g., the signal output from LNA 506A) to baseband, and baseband filter 510A filters the baseband signal conveyed by mixer 508A. Furthermore, a signal received at input 501 and a signal generated at inductor L2 (e.g., via inductive coupling of inductor L1 and L2) are conveyed to LNA 506B, which provides amplification based on the signal received at node B and the signal received at node D. Further, mixer 508B downconverts an amplified signal (e.g., the signal output from LNA 506B) to baseband, and baseband filter 510B filters the baseband signal conveyed by mixer 508B.

According to one example, in power-mode operation (in which power is more important), LNA 506A and/or LNA 506B may comprise a 50 ohm input impedance, and a first stage LNA (e.g., an external LNA) may have fixed gain with a 50 ohm load. In addition, device 500 may still provide superior IIP3 performance (by way of example only e.g., >18 dBm) in both non-CA/inter-CA and intra-CA modes.

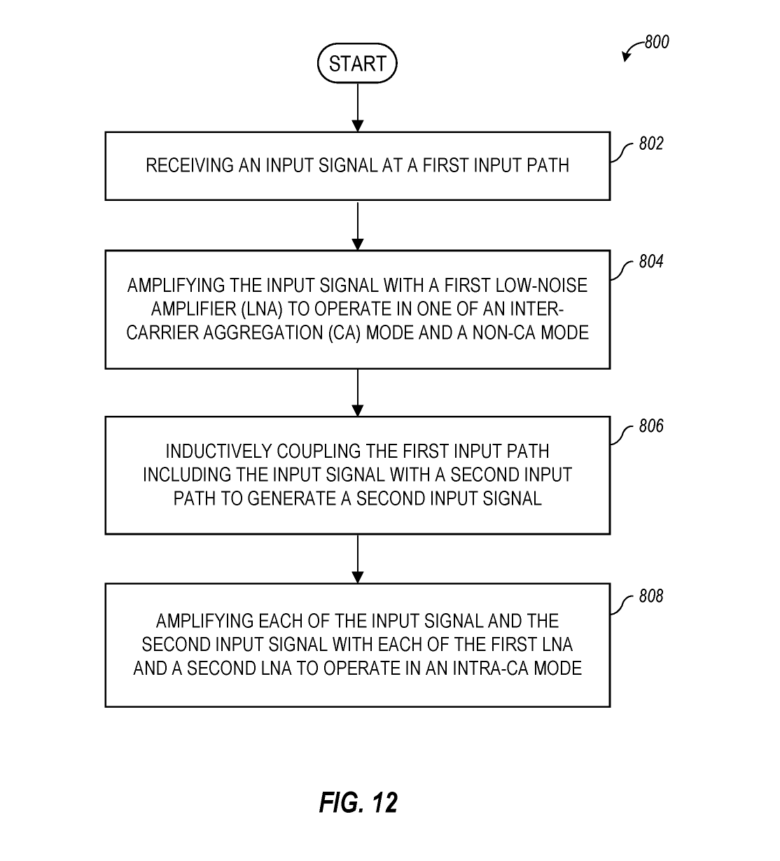

FIG. 12 is a flowchart illustrating a method 800, in accordance with aspects of the present disclosure. Method 800 may include receiving an input signal at a first input path (depicted by numeral 802). Method 800 may also include amplifying the input signal with a first low-noise amplifier (LNA) to operate in one of an inter-carrier aggregation (CA) mode and a non-CA mode (depicted by numeral 804). Further, method 800 may include inductively coupling the first input path including the input signal with a second input path to generate a second input signal (depicted by numeral 806). Moreover, method 800 may include amplifying each of the input signal and the second input signal with each of the first LNA and a second LNA to operate in an intra-CA mode (depicted by numeral 808).

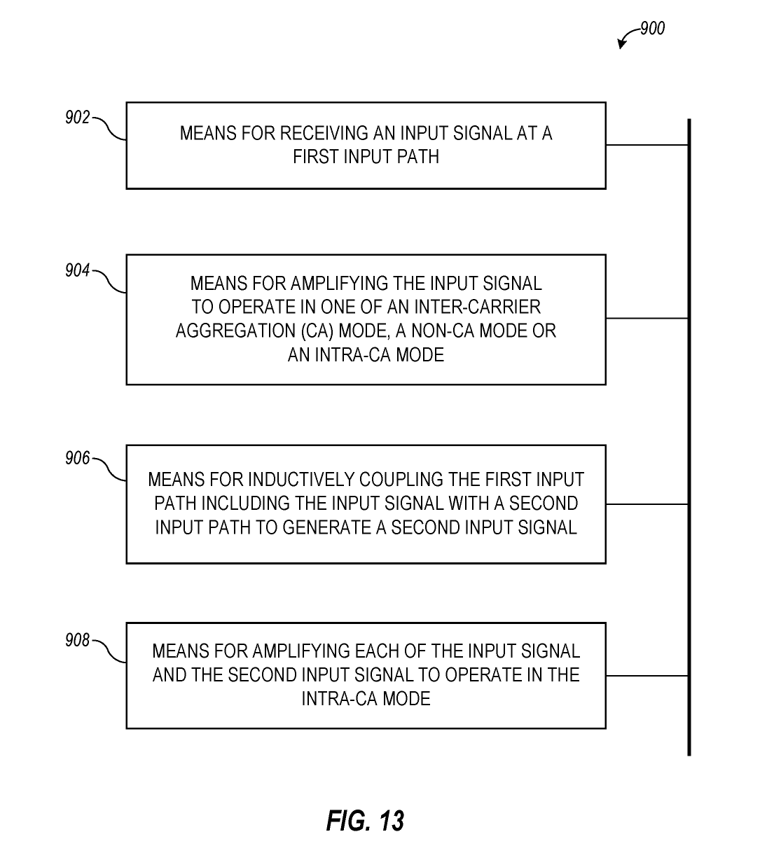

FIG. 13 illustrates a receiver device 900 in accordance with aspects of the present disclosure. In one aspect, device 900 is implemented by one or more modules configured to provide the functions as described herein. For example, in an aspect, each module comprises hardware and/or hardware executing software.

Device 900 comprises a first module comprising means (902) for receiving an input signal at a first input path. For example, means 902 may comprise input 501 (see e.g., FIG. 6)

Device 900 also comprises a second module comprising means (904) for amplifying the input signal to operate in one of an inter-carrier aggregation (CA) mode, a non-CA mode, or an intra-CA mode. For example, means 904 may comprise LNA 506A (see e.g., FIG. 6).

Device 900 further comprises a third module comprising means (906) for inductively coupling the first input path including the input signal with a second input path to generate a second input signal. For example, means 906 may comprise transformer 502 (see e.g., FIG. 6).

Moreover, device 900 includes a fourth module comprising means (908) for amplifying each of the input signal and the second input signal to operate in the intra-CA mode. For example, means 908 may comprise LNA 506A and LNA 506B (see e.g., FIG. 6).

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure. Thus, the present disclosure is not intended to be limited to the aspects shown herein but is to be accorded the widest scope consistent with the principles and novel features disclosed herein.

1. A device, comprising:
at least one low-noise amplifier (LNA);
a first input path configured to convey a first signal to a first input of the at least one LNA;
a second input path configured to convey a second signal to a second input of the at least one LNA, the first input path and the second input path configured to be selectable based at least in part on a mode of operation; and
a transformer configured to inductively couple the first input path to the second input path.

2. The device of claim 1, wherein the at least one LNA comprises a first LNA and a second LNA, the first input path configured to convey the first signal to each of the first LNA and the second LNA, and the second input path configured to convey the second signal to each of the first LNA and the second LNA to operate in a carrier aggregation (CA) mode.

3. The device of claim 2, wherein the CA mode comprises intra-CA mode.

4. The device of claim 1, wherein the first input path is configured to convey the first signal to the first input of a single LNA of the at least one LNA to operate in one of an inter-carrier aggregation (CA) mode or a non-CA mode.

5. The device of claim 1, further comprising:
a mixer coupled to an output of the at least one LNA; and
a baseband filter coupled to an output of the mixer.

6. The device of claim 1, further comprising:
a transistor coupled to an inductor of the second input path; and
a resistor coupled between a ground and the transistor.

7. The device of claim 6, wherein an input impedance of the at least one LNA is adjusted via the transistor and the resistor.

8. The device of claim 1, wherein one or more of a plurality of transistors of the at least one LNA are selectively configured to operate in a conductive state to operate the device in one of a plurality of modes.

9. The device of claim 1, wherein each LNA of the at least one LNA comprises:
a first path including the first input and a first plurality of transistors; and
a second path coupled to the first path and including the second input and a second plurality of transistors; and
the transformer including:
first and second inductors coupled to each of the first path and the second path; and
a third inductor coupled to an output and configured to inductively couple to the first and second inductors.

10. The device of claim 1, wherein the transformer includes a first inductor in the first input path and a second inductor in the second input path.

11. The device of claim 1, wherein a single LNA of the at least one LNA is configured to operate during one of an inter-carrier aggregation (CA) mode, a non-CA mode or an intra-CA mode, and a plurality of LNAs of the at least one LNA are configured to operate during the intra-CA mode.

12. The device of claim 1, wherein an input impedance of the at least one LNA is adjustable via at least one of the second input path and the at least one LNA.

13. The device of claim 1, wherein the second input path includes a transistor for switchable coupling an inductor of the second input path to ground.

14. The device of claim 1, further comprising a receiver including the at least one LNA, the first input path, the second input path, and the transformer.

15. A method, comprising:
receiving a first input signal at a first input path;
amplifying the first input signal with a first low-noise amplifier (LNA) to operate in one of an inter-carrier aggregation (CA) mode, a non-CA mode, or an intra-CA mode;
inductively coupling the first input path including the first input signal with a second input path to generate a second input signal; and
amplifying each of the first input signal and the second input signal with each of the first LNA and a second LNA to operate in the intra-CA mode; and wherein:
the first input path and the second input path are configured to be selectable based at least in part on a mode of operation.

16. The method of claim 15, further comprising adjusting an input impedance of at least the first LNA.

17. The method of claim 16, wherein adjusting comprises coupling the second input path to ground via a resistor.

18. The method of claim 15, further comprising amplifying each of the first input signal and the second input signal with the first LNA while operating in one of the inter-CA mode and the non-CA mode.

19. A device, comprising:
means for receiving a first input signal at a first input path;
means for amplifying the first input signal to operate in one of an inter-carrier aggregation (CA) mode, a non-CA mode, or an intra-CA mode;
means for inductively coupling the first input path including the first input signal with a second input path to generate a second input signal, the first input path and the second input path configured to be selectable based at least in part on a mode of operation; and
means for amplifying each of the first input signal and the second input signal to operate in the intra-CA mode.

20. The device of claim 19, further comprising means for adjusting an input impedance of the means for amplifying the first input signal.

21. The device of claim 20, further comprising means for amplifying each of the first input signal and the second input signal with the means for amplifying the first input signal while operating in one of the inter-CA mode or the non-CA mode.
